(19) United States
(12) Patent Application Publication
(10) Pub. No.: US 2022/0117123 A1
(43) Pub. Date: Apr. 14, 2022

(54) HEAT DISSIPATING ELEMENT CONTROL METHOD, AND CONTROL APPARATUS

(71) Applicant: HUAWEI DIGITAL POWER TECHNOLOGIES CO., LTD., Shenzhen (CN)

(72) Inventors: Junjie LI, Shanghai (CN); Xinyu YU, Shanghai (CN); Kai XIN, Shanghai (CN); Jiaguang FU, Shanghai (CN)

(21) Appl. No.: 17/558,917

(22) Filed: Dec. 22, 2021

Related U.S. Application Data
(63) Continuation of application No. PCT/CN2020/083615, filed on Apr. 8, 2020.

(30) Foreign Application Priority Data
Aug. 13, 2019 (CN) 201910745537.3

(51) Int. Cl. H05K 7/20

(52) U.S. Cl. CPC H05K 7/20945; H05K 7/20909

(57) ABSTRACT

Embodiments of this application disclose a heat dissipating element control method, including: obtaining a status parameter set and a detected temperature of a first device, where the status parameter set is associated with a running temperature of the first device; determining values of a first temperature parameter and a second temperature parameter in a target adjustment function based on the status parameter set; and determining the heat dissipating efficiency of the heat dissipating element based on the values of the first temperature parameter and the second temperature parameter and the detected temperature, and controlling running of the heat dissipating element. This resolves a problem that the heat dissipating efficiency is not adjusted in time because the detected temperature is unable to reflect an actual temperature in real time.

### CROSS-REFERENCE TO RELATED APPLICATIONS

This application is a continuation of International Application No. PCT/CN2020/083615, filed on Apr. 8, 2020, which claims priority to Chinese Patent Application No. 201910745537.3, filed on Aug. 13, 2019. The disclosures of the aforementioned applications are hereby incorporated by reference in their entireties.

### BACKGROUND

With industrial development, power levels of various electronic devices, such as an inverter, are gradually increased. The inverter is a power converter that converts a direct current into an alternating current by using a power electronics technology. In various high-power electronic devices, power consumption generated by a core component of the high-power electronic device is usually a main part of power consumption of the entire electronic device. Due to high power consumption, the core component generates a large amount of heat when running in the high-power electronic device. Therefore, a heat dissipating element, such as a fan heat dissipating element or a water-cooled heat dissipating element, needs to be configured in the electronic device, and effective cooling and heat dissipating need to be performed on the heat emitting component by using the heat dissipating element, to prevent the component from being burnt due to an excessively high running temperature of the component.

A component on which cooling and heat dissipating need to be performed by using a heat dissipating element is referred to as a heat emitting element. Higher heat dissipating efficiency of the heat dissipating element indicates a better heat dissipating effect of the heat dissipating element for the heat emitting element, and also indicates a shorter service life of the heat dissipating element. Therefore, to ensure safe running of the heat emitting element and also increase a service life of the heat dissipating element, heat dissipating efficiency of the heat dissipating element needs to be correspondingly adjusted based on a detected temperature of the heat emitting element. Currently, an adjustment method widely used in the industry is a table lookup method. That is, based on a detected temperature of a heat emitting element, heat dissipating efficiency corresponding to the detected temperature is queried in a preset mapping relationship table, to output a corresponding control instruction to control running of a heat dissipating element. In this method, a change in heat dissipating efficiency of the heat dissipating element is shown in FIG. 1. In this method, if higher control accuracy needs to be achieved, a large quantity of points need to be set in the preset mapping relationship table. As a result, the mapping relationship table occupies excessively large storage space, and a table lookup execution period is longer. If a quantity of points is excessively small, a large temperature range corresponds to one heat dissipating efficiency value. Therefore, heat dissipating efficiency switching is not smooth enough. In addition, for compatibility with a high temperature state, heat dissipating efficiency corresponding to each temperature range is usually set to be large, affecting a service life of the heat dissipating element.

In addition, the detected temperature of the heat emitting element is usually detected by an additional temperature detection element, and the heat emitting element is connected to the temperature detection element by using a connection apparatus. However, due to thermal resistance, the temperature detection element has specific hysteresis in detecting an actual temperature of the heat emitting element. When a running status of an electronic device suddenly changes, a temperature of a heat emitting element in the electronic device accordingly changes rapidly. However, a temperature detection element is unable to reflect an actual temperature of the heat emitting element in real time, that is, a detected temperature of the heat emitting element is different from the actual temperature. In addition, a fixed mapping relationship table is possibly inapplicable to a working condition after the running status suddenly changes. Therefore, heat dissipating efficiency of a heat dissipating element is unable to be adjusted in time based on the fixed mapping relationship table and the detected temperature of the heat emitting element, affecting safe running of the heat emitting element.

### SUMMARY

Embodiments of this application provide a heat dissipating element control method, and a control apparatus, so that heat dissipating efficiency of a heat dissipating element is adjusted in real time when a running status of a high-power device changes, to determine corresponding heat dissipating efficiency in advance when a detected temperature of a heat emitting element does not change. This resolves a problem that the heat dissipating efficiency is not adjusted in time because the detected temperature is unable to reflect an actual temperature in real time.

In view of this, a first aspect of the embodiments of this application provides a heat dissipating element control method. The control method includes: obtaining a status parameter set and a detected temperature of a first device, where the status parameter set includes at least one running status parameter, the at least one running status parameter is a parameter that affects a temperature of the first device when the first device runs, and the detected temperature is a temperature detected by a temperature detection element inside the first device for a heat emitting element; determining values of a first temperature parameter and a second temperature parameter in a target adjustment function based on the status parameter set, where the target adjustment function is a function with the detected temperature being an independent variable and heat dissipating efficiency of a heat dissipating element being a dependent variable; and determining the heat dissipating efficiency of the heat dissipating element based on a value of the first temperature parameter, a value of the second temperature parameter, and the detected temperature, and controlling running of the heat dissipating element based on the heat dissipating efficiency.

The values of the first temperature parameter and the second temperature parameter in the target adjustment function are determined based on the status parameter set of the first device, that is, when a running status parameter of the first device changes, the values of the first temperature parameter and the second temperature parameter in the target adjustment function also change accordingly, so that the target adjustment function outputs correct heat dissipating efficiency of the heat dissipating element when the detected temperature does not change, to control the heat dissipating element to run based on heat dissipating efficiency in an actual condition. Therefore, the heat dissipating efficiency of the heat dissipating element is adjusted in advance without a need to wait for hysteresis duration for changing of the detected temperature, thereby resolving a problem that the heat dissipating efficiency of the heat dissipating element is unable to be adjusted in time because after the running status parameter of the first device changes, an actual temperature of the heat emitting element in the first device rapidly changes, but the detected temperature is unable to change in real time with the actual temperature of the heat emitting element.

Optionally, with reference to the first aspect, in a first possible implementation, the determining a value of a first temperature parameter in a target adjustment function based on the status parameter set includes: determining, from the status parameter set, a running status parameter associated with the first temperature parameter, to obtain a first associated parameter set; and determining the value of the first temperature parameter based on a preset first mapping relationship function and the first associated parameter set, where the first mapping relationship function is used to represent a mapping relationship between the running status parameter in the first associated parameter set and the first temperature parameter. Fast operation is performed by using the pre-built first mapping relationship function and the first associated parameter set, to obtain the value of the first temperature parameter.

Optionally, with reference to the first possible implementation of the first aspect, in a second possible implementation, in the first mapping relationship function, the value of the first temperature parameter is a difference between a preset maximum value of the first temperature parameter and a first adjustment value, and the first adjustment value is obtained by performing weighted summation on values of running status parameters in the first associated parameter set based on weight values respectively corresponding to the running status parameters in the first associated parameter set.

Optionally, with reference to the second possible implementation of the first aspect, in a third possible implementation, the control method further includes: determining, based on a user instruction, the weight values respectively corresponding to the running status parameters in the first associated parameter set, to meet different value parameters in a plurality of different actual cases.

Optionally, with reference to any one of the first aspect or the first to the third possible implementations of the first aspect, in a fourth possible implementation, the determining a value of a second temperature parameter in a target adjustment function based on the status parameter set includes: determining, from the status parameter set, a running status parameter associated with the second temperature parameter, to obtain a second associated parameter set; and determining the value of the second temperature parameter based on a preset second mapping relationship function and the second associated parameter set, where the second mapping relationship function is used to represent a mapping relationship between the running status parameter in the second associated parameter set and the second temperature parameter. Fast operation is performed by using the pre-built second mapping relationship function and the second associated parameter set, to obtain the value of the second temperature parameter.

Optionally, with reference to the fourth possible implementation of the first aspect, in a fifth possible implementation, in the second mapping relationship function, the value of the second temperature parameter is a difference between a preset maximum value of the second temperature parameter and a second adjustment value, the second adjustment value is associated with a preset adjustment threshold and a ratio of a value of a target running status parameter to a rated value corresponding to the target running status parameter, and the target status parameter is a running status parameter in the second associated parameter set.

Optionally, with reference to any one of the first aspect or the first to the fifth possible implementations of the first aspect, in a sixth possible implementation, when the first device is an inverter, the status parameter set includes a direct current bus voltage, an output current, a switching frequency, a modulation scheme parameter, and a power factor.

A second aspect of the embodiments of this application provides a control apparatus. The control apparatus includes:

an obtaining unit, configured to obtain a status parameter set and a detected temperature of a first device, where the status parameter set includes at least one running status parameter, and the at least one running status parameter is a parameter that affects a temperature of the first device when the first device runs;

a first determining unit, configured to determine a value of a first temperature parameter in a target adjustment function based on the status parameter set, where the target adjustment function is a function with the detected temperature being an independent variable and heat dissipating efficiency of a heat dissipating element being a dependent variable;

a second determining unit, configured to determine a value of a second temperature parameter in the target adjustment function based on the status parameter set;

a third determining unit, configured to determine the heat dissipating efficiency of the heat dissipating element based on the value of the first temperature parameter, the value of the second temperature parameter, and the detected temperature; and

a control unit, configured to control running of the heat dissipating element based on the heat dissipating efficiency of the heat dissipating element.

Optionally, with reference to the second aspect, in a first possible implementation, the first determining unit is configured to determine, from the status parameter set, a running status parameter associated with the first temperature parameter, to obtain a first associated parameter set; and the first determining unit is further configured to determine the value of the first temperature parameter based on a preset first mapping relationship function and the first associated parameter set, where the first mapping relationship function is used to represent a mapping relationship between the running status parameter in the first associated parameter set and the first temperature parameter.

Optionally, with reference to the first possible implementation of the second aspect, in a second possible implementation, in the first mapping relationship function, the value of the first temperature parameter is a difference between a preset maximum value of the first temperature parameter and a first adjustment value, and the first adjustment value is obtained by performing weighted summation on values of running status parameters in the first associated parameter set based on weight values respectively corresponding to the running status parameters in the first associated parameter set.

Optionally, with reference to the second possible implementation of the second aspect, in a third possible implementation, the control apparatus further includes: a fourth determining unit, configured to determine, based on a user instruction, the weight values respectively corresponding to the running status parameters in the first associated parameter set.

Optionally, with reference to any one of the second aspect or the first to the third possible implementations of the second aspect, in a fourth possible implementation, the second determining unit is configured to determine, from the status parameter set, a running status parameter associated with the second temperature parameter, to obtain a second associated parameter set; and the second determining unit is further configured to determine the value of the second temperature parameter based on a preset second mapping relationship function and the second associated parameter set, where the second mapping relationship function is used to represent a mapping relationship between the running status parameter in the second associated parameter set and the second temperature parameter.

Optionally, with reference to the fourth possible implementation of the second aspect, in a fifth possible implementation, in the second mapping relationship function, the value of the second temperature parameter is a difference between a preset maximum value of the second temperature parameter and a second adjustment value, the second adjustment value is associated with a preset adjustment threshold and a ratio of a value of a target running status parameter to a rated value corresponding to the target running status parameter, and the target status parameter is a running status parameter in the second associated parameter set.

A third aspect of the embodiments of this application provides a control apparatus. The control apparatus includes a processor, the processor is coupled to a memory, the memory is configured to store an instruction, the processor is configured to execute the instruction stored in the memory, and the execution of the instruction stored in the memory enables the processor to execute the heat dissipating element control method in any one of the first aspect or the possible implementations of the first aspect. Optionally, the control apparatus further includes the memory.

A fourth aspect of this application provides a computer-readable storage medium. The computer-readable storage medium stores an instruction. When the instruction runs on a computer, the computer is enabled to execute the heat dissipating element control method in any one of the first aspect or the possible implementations of the first aspect.

A fifth aspect of this application provides a computer program product. When the computer program product runs on a computer, the computer is enabled to execute the heat dissipating element control method in any one of the first aspect or the possible implementations of the first aspect.

In the embodiments of this application, first, the status parameter set and the detected temperature of the first device are obtained, where the status parameter set includes the at least one running status parameter, the at least one running status parameter is a parameter that affects the temperature of the first device when the first device runs, and the detected temperature is a detected temperature of a heat emitting element in the first device; then, the value of the first temperature parameter and the value of the second temperature parameter in the target adjustment function are determined based on the status parameter set, where the target adjustment function is a function with the detected temperature of the first device being an independent variable and the heat dissipating efficiency of the heat dissipating element being a dependent variable; and after the values of the first temperature parameter and the second temperature parameter are determined, the heat dissipating efficiency of the heat dissipating element is determined based on the value of the first temperature parameter, the value of the second temperature parameter, and the detected temperature, and running of the heat dissipating element is controlled based on the determined heat dissipating efficiency of the heat dissipating element. In this solution, the values of the first temperature parameter and the second temperature parameter in the target adjustment function are determined based on the status parameter set of the first device, that is, when a running status parameter of the first device changes, the values of the first temperature parameter and the second temperature parameter in the target adjustment function also change accordingly, so that the target adjustment function outputs correct heat dissipating efficiency of the heat dissipating element when the detected temperature does not change, to control the heat dissipating element to run based on heat dissipating efficiency in an actual condition. Therefore, the heat dissipating efficiency of the heat dissipating element is adjusted in advance without a need to wait for hysteresis duration for changing of the detected temperature, thereby resolving a problem that the heat dissipating efficiency of the heat dissipating element is unable to be adjusted in time because after the running status parameter of the first device changes, an actual temperature of the heat emitting element in the first device rapidly changes, but the detected temperature is unable to change in real time with the actual temperature of the heat emitting element. This effectively protects the heat emitting element in the first device from running at a high temperature and being burnt because the temperature of the heat emitting element rapidly rises, but the heat dissipating efficiency of the heat dissipating element is not high enough; and also reduces the heat dissipating efficiency of the heat dissipating element in time when the actual temperature of the heat emitting element rapidly drops, thereby helping increase a life of the heat dissipating element. In this solution, the values of the first temperature parameter and the second temperature parameter in the target adjustment function is updated in real time when the first device is in different working conditions, that is, has different running status parameters. This resolves a problem that an adjustment rate of the heat dissipating efficiency of the heat dissipating element is unable to keep pace with a change rate of the actual temperature of the heat emitting element after the running status parameter changes. In addition, the heat dissipating efficiency of the heat dissipating element is calculated by using the target adjustment function, so that continuous adjustment is performed in real time based on the detected temperature. This implements smooth heat dissipating efficiency switching.

### BRIEF DESCRIPTION OF DRAWINGS

FIG. 1 is a schematic diagram of a change status of heat dissipating efficiency in a table lookup method;

FIG. 2 is a schematic diagram of a system architecture of a technical solution of this application;

FIG. 3 is a schematic diagram of an embodiment of a heat dissipating element control method according to an embodiment of this application;

FIG. 4 is a schematic diagram of another embodiment of a heat dissipating element control method according to an embodiment of this application;

FIG. 5 is a schematic diagram of function curves of target adjustment functions corresponding to different status parameter sets according to an embodiment of this application;

FIG. 6A and FIG. 6B are a schematic diagram of implementation effect comparison between a technical solution of this application and a table lookup solution;

FIG. 7 is a schematic diagram of an embodiment of a control apparatus according to an embodiment of this application; and

FIG. 8 is a schematic diagram of another embodiment of a control apparatus according to an embodiment of this application.

### DESCRIPTION OF EMBODIMENTS

The following describes the embodiments of this application with reference to the accompanying drawings. Clearly, the described embodiments are merely some rather than all of the embodiments of this application. With evolution of a graph computing framework and emergence of a new application scenario, the technical solutions provided in the embodiments of this application are also applicable to a similar technical problem.

In the specification, claims, and accompanying drawings of this application, the terms such as “first” and “second” are intended to distinguish between similar objects but do not necessarily indicate a specific order or sequence. The data termed in such a way is interchangeable in a proper circumstance so that the embodiments described herein is implemented in an order other than the order illustrated or described herein. Moreover, the terms “include”, “have”, and any other variants are intended to cover the non-exclusive inclusion. For example, a process, method, system, product, or device that includes a list of steps or modules is not necessarily limited to those steps or modules expressly listed, but includes other steps or modules not expressly listed or inherent to such a process, method, system, product, or device. The names or numbers of the steps in this application do not mean that the steps in the method procedure are executed according to the time/logical order indicated by the names or numbers, and the execution order of the procedure steps that have been named or numbered is changed based on the to-be-achieved technical objective, provided that the same or similar technical effects is achieved. Division into the modules in this application is logical division. During implementation in an actual application, another division manner is used. For example, a plurality of modules are combined or integrated into another system, or some features are ignored or not executed. In addition, the displayed or discussed mutual couplings or direct couplings or communication connections are implemented by using some interfaces. The indirect couplings or communication connections between the modules are implemented in electronic or other similar forms. This is not limited in this application. In addition, modules described as separate components are physically separated or are unable to be physically separated, or are physical modules or are unable to be physical modules, or are unable to be distributed in a plurality of circuit modules. Some or all of the modules are selected based on an actual parameter, to achieve the objectives of the solutions of this application.

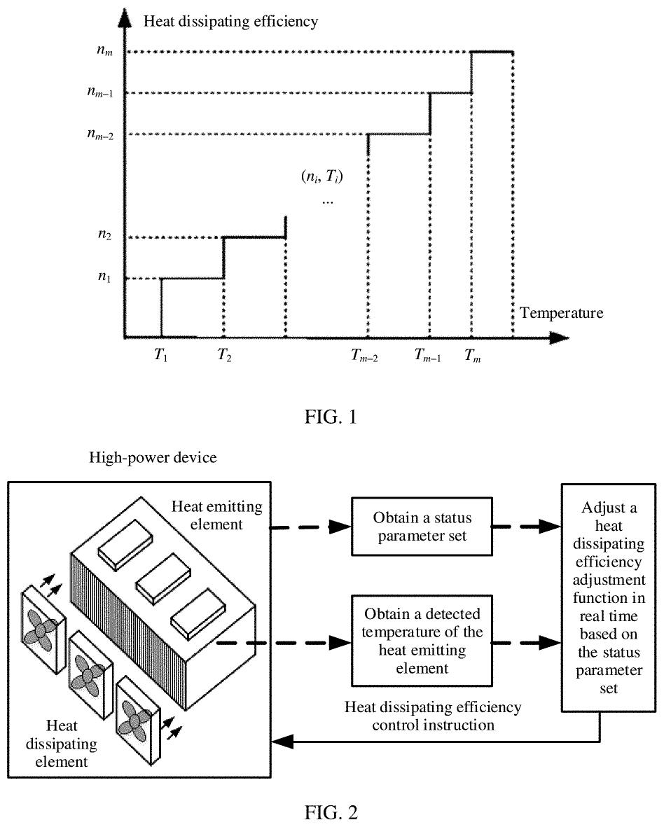

The embodiments of this application are applied to various high-power electronic devices, for example, conversion devices, such as an inverter and a transformer, applied to a power grid system, and radio devices, such as a high-power base station and radar. These high-power electronic devices are characterized by being prone to emit heat. Inside these devices, some elements (including a chip or a circuit) emit large amounts of heat. Therefore, special heat dissipating elements (such as heat dissipating fans or water-cooled heat sinks) need to be configured in these devices to dissipate heat for these elements that emit large amounts of heat. A system architecture of a technical solution of this application is shown in FIG. 2. A status parameter set of a high-power device is obtained and a heat dissipating efficiency adjustment function of a heat dissipating element is adjusted in real time based on the status parameter set; and heat dissipating efficiency of the heat dissipating element is output based on a detected temperature of a heat emitting element, to deliver a corresponding heat dissipating efficiency control instruction to the heat dissipating element to control the heat dissipating element to dissipate heat for the heat emitting element. The status parameter set includes at least one running status parameter that affects a temperature of the device when the high-power device runs. An inverter is used as an example. The inverter mainly includes a direct current input module, an alternating current output module, a heat dissipating fan, a heat sink, a power module, and a temperature detection element. The power module is a core component of the inverter, and is an electronic switch component. A switch chip in the power module controls electric energy conversion through on/off switching. The power module is a component with a largest power consumption ratio in the inverter, and is a main generation unit of an amount of emitted heat of the inverter. The heat dissipating fan and the heat sink are collectively referred to as a heat dissipating element. The power module is installed on the heat sink. The heat dissipating fan actively drives the heat sink to perform air cooling and heat dissipating. The heat sink passively dissipates heat for the power module based on an air flow agitated by the heat dissipating fan. The temperature detection element is configured to detect a temperature of the switch chip in the power module. Heat dissipating efficiency of the heat dissipating element is adjusted based on a temperature detected by the temperature detection element, to ensure that the power module runs within an allowed temperature range and increase a service life of the heat dissipating element.

To resolve a problem, in an existing adjustment manner of heat dissipating efficiency of a heat dissipating element, that heat dissipating efficiency switching is not smooth and heat dissipating efficiency is unable to be adjusted in time when a running status of a device suddenly changes, the embodiments of this application provide a heat dissipating element control method. The embodiments of this application further provide a corresponding control apparatus. The following separately provides detailed descriptions.

In the embodiments of this application, the heat dissipating element control method provided in the embodiments of this application are executed by the control apparatus provided in the embodiments of this application. The control apparatus are a chip, or a circuit. The control apparatus is configured to control heat dissipating efficiency used by a heat dissipating element in a high-power electronic device during running. The control apparatus are integrated into the high-power electronic device; or independent of the high-power electronic device, and coupled to an internal element of the high-power electronic device by using a connection apparatus. This is not limited in this application.

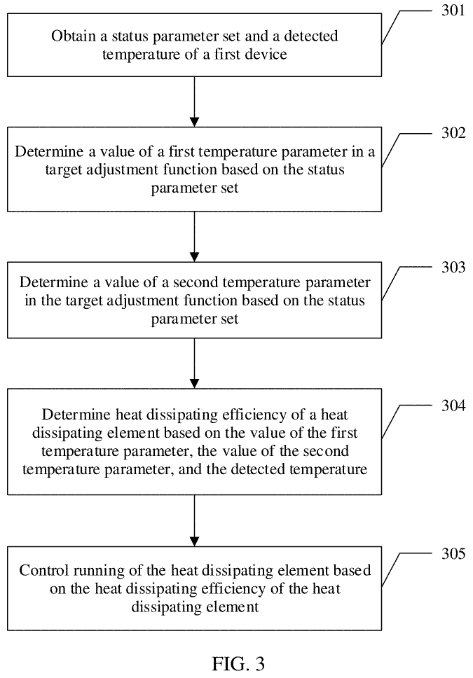

FIG. 3 is a schematic diagram of an embodiment of a heat dissipating element control method according to an embodiment of this application.

As shown in FIG. 3, this embodiment includes the following steps.

301. Obtain a status parameter set and a detected temperature of a first device.

In this embodiment, the status parameter set includes at least one running status parameter, and the at least one running status parameter is a parameter that affects a temperature of the first device when the first device runs. The at least one running status parameter directly affects power consumption of the first device, and therefore indirectly affects the temperature of the first device. The detected temperature is a detected temperature of a heat emitting element in the first device, and the detected temperature is detected by a temperature detection element in the first device. However, due to thermal resistance, the temperature detection element is unable to reflect an actual temperature change in the heat emitting element in real time, that is, the detected temperature is unable to change with an actual temperature of the heat emitting element. The status parameter set of the first device reflects an actual temperature change trend of the heat emitting element. A value of a parameter in a target adjustment function is determined based on the status parameter set. The target adjustment function is a function with the detected temperature being an independent variable and heat dissipating efficiency of a heat dissipating element being a dependent variable. After the value of the parameter in the target adjustment function is determined based on the status parameter set, the target adjustment function is enabled to output heat dissipating efficiency corresponding to the actual temperature of the heat emitting element even when the detected temperature has not changed, to meet a heat dissipating parameter of the heat emitting element at the actual temperature.

In this embodiment, the heat dissipating element corresponds to different types of heat dissipating apparatuses, and the heat dissipating efficiency corresponds to different parameters. For example, when the heat dissipating element is a combination of a fan and a heat sink, the heat dissipating efficiency corresponds to a rotation speed, a duty cycle, or a working voltage of the fan. When the heat dissipating apparatus is a water-cooled heat sink, the heat dissipating efficiency corresponds to a cooling water flow rate or running power of a water flow driven motor. This is not limited herein in this application.

302. Determine a value of a first temperature parameter in the target adjustment function based on the status parameter set.

In this embodiment, the first temperature parameter is a parameter in the target adjustment function. When the status parameter set of the first device does not change, the first temperature parameter is equivalent to a constant in the target adjustment function. However, when the status parameter set of the first device changes, the value of the first temperature parameter needs to be re-determined based on a changed status parameter set, so that heat dissipating efficiency output by the target adjustment function meets an actual temperature status of the heat emitting element. The heat dissipating efficiency output by the target adjustment function is adjusted even when the detected temperature has not changed, so that the heat dissipating efficiency of the heat dissipating element is adjusted in advance to meet the heat dissipating parameter of the heat emitting element at the actual temperature.

303. Determine a value of a second temperature parameter in the target adjustment function based on the status parameter set.

In this embodiment, similar to the first temperature parameter, the second temperature parameter is also a parameter in the target adjustment function. When the status parameter set of the first device does not change, the second temperature parameter is also equivalent to a constant in the target adjustment function. However, when the status parameter set of the first device changes, the value of the second temperature parameter needs to be re-determined based on a changed status parameter set. After the values of the first temperature parameter and the second temperature parameter are determined based on the status parameter set, heat dissipating efficiency output by the target adjustment function meets an actual temperature status of the heat emitting element. The heat dissipating efficiency output by the target adjustment function is adjusted even when the detected temperature has not changed. This resolves a problem that the heat dissipating efficiency of the heat dissipating element is unable to be adjusted in time because the detected temperature is unable to reflect the actual temperature of the heat emitting element in real time after a running status parameter of the first device changes.

304. Determine the heat dissipating efficiency of the heat dissipating element based on the value of the first temperature parameter, the value of the second temperature parameter, and the detected temperature.

In this embodiment, because the target adjustment function is a function with the detected temperature being an independent variable and the heat dissipating efficiency of the heat dissipating element being a dependent variable, after the value of the first temperature parameter and the value of the second temperature parameter are determined, the detected temperature is used as an input for the target adjustment function, to output the heat dissipating efficiency of the heat dissipating element.

305. Control running of the heat dissipating element based on the heat dissipating efficiency of the heat dissipating element.

In this embodiment, after the heat dissipating efficiency of the heat dissipating element is determined based on the value of the first temperature parameter, the value of the second temperature parameter, and the detected temperature by using the target adjustment function, a corresponding control instruction is generated based on the heat dissipating efficiency, and the control instruction is sent to the heat dissipating element, to control the heat dissipating element to run based on the heat dissipating efficiency.

In this embodiment, the values of the first temperature parameter and the second temperature parameter in the target adjustment function are determined based on the status parameter set of the first device, that is, when the running status parameter of the first device changes, the values of the first temperature parameter and the second temperature parameter in the target adjustment function also change accordingly, so that the target adjustment function outputs correct heat dissipating efficiency of the heat dissipating element when the detected temperature does not change, to control the heat dissipating element to run based on heat dissipating efficiency in an actual condition. Therefore, the heat dissipating efficiency of the heat dissipating element is adjusted in advance without a need to wait for hysteresis duration for changing of the detected temperature, thereby resolving a problem that the heat dissipating efficiency of the heat dissipating element is unable to be adjusted in time because after the running status parameter of the first device changes, an actual temperature of the heat emitting element in the first device rapidly changes, but the detected temperature is unable to change in real time with the actual temperature of the heat emitting element. This effectively protects the heat emitting element in the first device from running at a high temperature and being burnt because the temperature of the heat emitting element rapidly rises, but the heat dissipating efficiency of the heat dissipating element is not high enough; and also reduces the heat dissipating efficiency of the heat dissipating element in time when the actual temperature of the heat emitting element rapidly drops, thereby helping increase a life of the heat dissipating element. In this solution, the values of the first temperature parameter and the second temperature parameter in the target adjustment function is updated in real time when the first device is in different working conditions, that is, has different running status parameters. This resolves a problem that an adjustment rate of the heat dissipating efficiency of the heat dissipating element is unable to keep pace with a change rate of the actual temperature of the heat emitting element after the running status parameter changes. In addition, the heat dissipating efficiency of the heat dissipating element is calculated by using the target adjustment function, so that continuous adjustment is performed in real time based on the detected temperature. This implements smooth heat dissipating efficiency switching.

In a specific embodiment, the first device in the foregoing embodiment is a high-power device such as an inverter or a transformer. A switch chip included in the inverter corresponds to the heat emitting element in the first device. The temperature detection element is an NTC resistor, configured to detect a temperature of the switch chip. The detected temperature of the switch chip is referred to as an NTC temperature. For ease of understanding, the following provides further detailed descriptions with reference to a specific running status parameter by using an example in which the first device is an inverter.

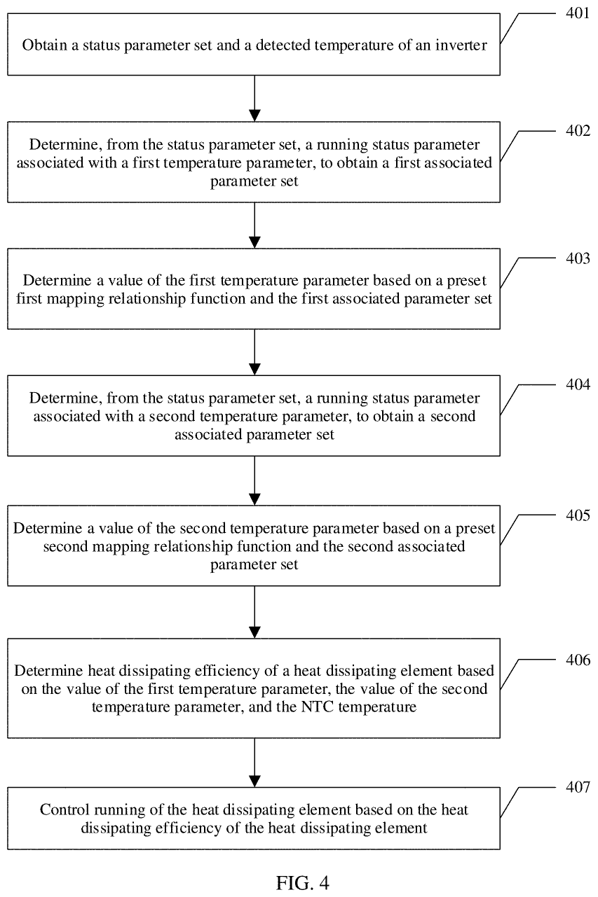

FIG. 4 is a schematic diagram of another embodiment of a heat dissipating element control method according to an embodiment of this application.

As shown in FIG. 4, this embodiment includes the following steps.

401. Obtain a status parameter set and a detected temperature of an inverter.

In this embodiment, the inverter corresponds to the foregoing first device, and the status parameter set of the inverter includes a direct current bus voltage, an output current, a switching frequency, a modulation scheme parameter, a power factor, and the like. The heat emitting element in the foregoing first device corresponds to a switch chip in the inverter in this embodiment, and the detected temperature in this embodiment is a detected temperature of the switch chip. Specific content of step 401 is similar to the specific content of step 301. For details, refer to the details in step 301. The details are not described herein again.

402. Determine, from the status parameter set, a running status parameter associated with a first temperature parameter, to obtain a first associated parameter set.

In this embodiment, the status parameter set of the inverter includes a plurality of types of running status parameters. However, a part of the running status parameters are strongly associated with the first temperature parameter. Therefore, the associated part of the running status parameters needs to be determined from the status parameter set, to obtain the first associated parameter set.

403. Determine a value of the first temperature parameter based on a preset first mapping relationship function and the first associated parameter set.

In this embodiment, when the obtained first associated parameter set of the inverter changes, a power consumption status of the inverter is affected, and further actual temperature change trends of the inverter and the switch chip in the inverter are affected. To match an actual temperature change trend of the switch chip and enable a target adjustment function to output heat dissipating efficiency that is of a heat dissipating element and that corresponds to an actual temperature of the switch chip, the first temperature parameter needs to be adjusted. Therefore, there is an indirect impact relationship between the first associated parameter set and the first temperature parameter. Therefore, in the technical solution of this application, the first mapping relationship function is pre-built based on the indirect impact relationship between the first associated parameter set and the first temperature parameter, so that the indirect impact relationship between the first associated parameter set and the first temperature parameter is converted into a direct mapping relationship between the first associated parameter set and the first temperature parameter. Based on the preset first mapping relationship, the value of the first temperature parameter is directly determined based on the first associated parameter set.

In the preset first mapping relationship function, the value of the first temperature parameter is a difference between a preset maximum value of the first temperature parameter and a first adjustment value, and the first adjustment value is obtained by performing weighted summation on values of running status parameters in the first associated parameter set based on weight values respectively corresponding to the running status parameters in the first associated parameter set. The preset maximum value of the first temperature parameter is used to set an upper limit of the value of the first temperature parameter, to optimize a value range of the first temperature parameter.

Optionally, the first associated parameter set includes five types of parameters: the direct current bus voltage, the output current, the switching frequency, the modulation scheme parameter, and the power factor. Correspondingly, a formula of the first mapping relationship function is as follows:

T_{full}=Tₘₐₓ−[α₁·i+a₂·u+α₃·pwm+α₄·fₛ+αₛ·(1−|pf|)], where

T_{full} is the first temperature parameter, Tₘₐₓ is the preset maximum value of the first temperature parameter, i is the output current, u is the direct current bus voltage, pwm is the modulation scheme parameter, the modulation scheme parameter is equal to 0 or 1, fₛ is the switching frequency, and pf is the power factor. When pwm=0, a modulation scheme of the inverter is a first modulation scheme, and the first modulation scheme is a discontinuous pulse width modulation (DPWM) scheme. When pwm=1, a modulation scheme of the inverter is a second modulation scheme, and the second modulation scheme is a sine pulse width modulation (SPWM) scheme. Preset α₁, α₂, α₃, α₄, and α₅ are respectively weight values corresponding to the output current, the direct current bus voltage, the modulation scheme parameter, the switching frequency, and the power factor. Because the output current, the direct current bus voltage, the modulation scheme parameter, the switching frequency, and the power factor affect power consumption of the inverter to different degrees, the output current, the direct current bus voltage, the modulation scheme parameter, the switching frequency, and the power factor also affect the value of the first temperature parameter to different degrees. α₁, α₂, α₃, α₄, and α₅ are respectively used to indicate degrees to which the output current, the direct current bus voltage, the modulation scheme parameter, the switching frequency, and the power factor affect the value of the first temperature parameter.

α₁, α₂, α₃, α₄, and αₛ are also associated with models of the heat dissipating element and a power module. Values of α₁, α₂, α₃, α₄, and α₅ is set based on various types of configurations of the inverter, to generate a corresponding weight value table. In an actual application, corresponding weight values are selected based on a user instruction, and the user instruction is entered by the user based on an actual configuration status of the inverter.

404. Determine, from the status parameter set, a running status parameter associated with a second temperature parameter, to obtain a second associated parameter set.

In this embodiment, the status parameter set of the inverter includes a plurality of types of running status parameters. However, a part of the running status parameters are strongly associated with the second temperature parameter. Therefore, the strongly associated part of the running status parameters needs to be determined from the status parameter set, to obtain the second associated parameter set.

405. Determine a value of the second temperature parameter based on a preset second mapping relationship function and the second associated parameter set.

In this embodiment, when the second associated parameter set of the inverter changes, a power consumption status of the inverter is affected, and further actual temperature change trends of the inverter and the switch chip in the inverter are affected. To match an actual temperature change trend of the switch chip and enable the target adjustment function to output heat dissipating efficiency that is of the heat dissipating element and that corresponds to an actual temperature of the switch chip, the second temperature parameter needs to be adjusted. Therefore, there is an indirect impact relationship between the second associated parameter set and the second temperature parameter. Therefore, in the technical solution of this application, the second mapping relationship function is pre-built based on the indirect impact relationship between the second associated parameter set and the second temperature parameter, so that the indirect impact relationship between the second associated parameter set and the second temperature parameter is converted into a direct mapping relationship between the second associated parameter set and the second temperature parameter. Based on the preset second mapping relationship, the value of the second temperature parameter is directly determined based on the second associated parameter set.

In the preset second mapping relationship function, the value of the second temperature parameter is a difference between a preset maximum value of the second temperature parameter and a second adjustment value, the second adjustment value is associated with a preset adjustment threshold and a ratio of a value of a target running status parameter to a rated value corresponding to the target running status parameter, and the target status parameter is a running status parameter in the second associated parameter set. The preset maximum value of the second temperature parameter is used to set an upper limit of the value of the second temperature parameter, to optimize a value range of the second temperature parameter. The preset adjustment threshold is used to control a value change range of the second temperature parameter.

Optionally, the target status parameter in the second associated parameter set is the output current of the inverter. The running status parameter is a running status parameter that affects the power consumption of the inverter to a greatest degree, and therefore the running status parameter also affects the value of the second temperature parameter to a greatest degree. A formula of the second mapping relationship function is as follows:

$${T}_{s t a r t} = {T}_{0} - {T}_{adjust} \cdot {( \frac{i}{{i}_{N}} )}^{2} ,$$

where

Tₛₜₐᵣₜ is the second temperature parameter, T₀ is the preset maximum value of the second temperature parameter, T_{adjust} is the preset adjustment threshold, i is the output current of the inverter, and i_{N} is a rated output current of the inverter. Because 0≤i≤i_{N}, a value range of

$${( \frac{i}{{i}_{N}} )}^{2}$$

is from 0 to 1. Therefore, the maximum value of Tₛₜₐᵣₜ is T₀, and a minimum value of Tₛₜₐᵣₜ is (T₀−T_{adjust}), that is, a value adjustment range of Tₛₜₐᵣₜ is T_{adjust}. Values of T₀ and T_{adjust} is set based on an actual case, and are not limited in this application.

406. Determine heat dissipating efficiency of the heat dissipating element based on the value of the first temperature parameter, the value of the second temperature parameter, and an NTC temperature (namely, the detected temperature).

In this embodiment, after the values of the first temperature parameter and the second temperature parameter are determined by using the first mapping relationship function and the second mapping relationship function, the heat dissipating efficiency of the heat dissipating element is determined based on the values of the first temperature parameter and the second temperature parameter, and the NTC temperature.

Optionally, to help reduce building difficulty of the target adjustment function and help calculate the heat dissipating efficiency, the target adjustment function is built as a linear function of one variable for which the NTC temperature is used as an independent variable and the heat dissipating efficiency is used as a dependent variable. A formula of the target adjustment function is as follows:

$${D}_{ref} = {D}_{s t a r t} + ( {D}_{full} - {D}_{s t a r t} ) \cdot \frac{{T}_{NTC} - {T}_{s t a r t}}{{T}_{full} - {T}_{s t a r t}} ,$$

where

D_{ref} is the heat dissipating efficiency of the heat dissipating element, D_{full} is a preset first heat dissipating efficiency threshold, T_{NTC} is the NTC temperature, the first heat dissipating efficiency threshold is maximum heat dissipating efficiency that is achieved during running of the heat dissipating element, Dₛₜₐᵣₜ is a preset second heat dissipating efficiency threshold, and the second heat dissipating efficiency threshold is minimum heat dissipating efficiency that is achieved when the heat dissipating element starts to run. In the target adjustment function, T_{full}>Tₛₜₐᵣₜ and correspondingly D_{full}>Dₛₜₐᵣₜ. When T_{NTC}≥Tₛₜₐᵣₜ, D_{ref}≥Dₛₜₐᵣₜ, and the heat dissipating element starts to operate. When T_{NTC}≥T_{full}, D_{ref}≥D_{full}, and the heat dissipating element runs based on the maximum heat dissipating efficiency (that is, the first heat dissipating efficiency threshold).

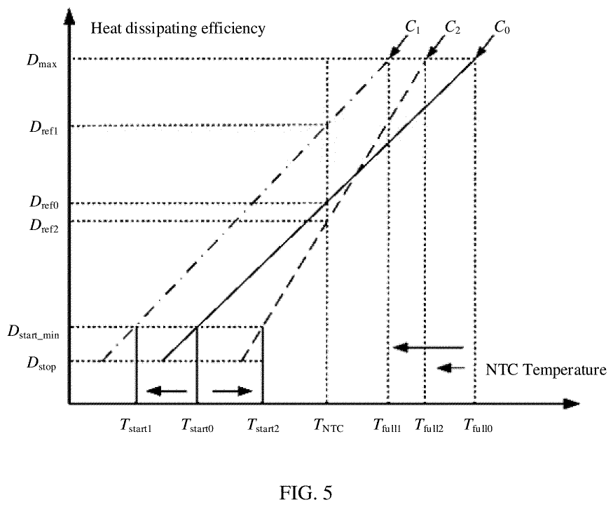

Because the first heat dissipating efficiency threshold and the second heat dissipating efficiency threshold are both preset values, when the obtained status parameter set of the inverter changes, the heat dissipating efficiency of the heat dissipating element is determined provided that the NTC temperature is obtained and the values of the first temperature parameter and the second temperature parameter are determined. As an example, referring to FIG. 5, C₀ is a function curve corresponding to the target adjustment function when the status parameter set has not changed, and C₁ and C₂ are respectively function curves corresponding to the target adjustment function after the values of the first temperature parameter and the second temperature parameter correspondingly change after the status parameter set changes in two cases. From FIG. 5, after the status parameter set changes, when the NTC temperature has not changed, C₀, C₁, and C₂ output different heat dissipating efficiency, and heat dissipating efficiency output by C₁ and C₂ meets heat dissipating parameters of the switch chip at actual temperatures to greater degrees.

407. Control running of the heat dissipating element based on the heat dissipating efficiency of the heat dissipating element.

In this embodiment, content of step 407 is similar to the content of step 305. For details, refer to the details in step 305. The details are not described herein again.

In a specific embodiment, to prevent the NTC temperature from fluctuating around Tₛₜₐᵣₜ to cause the heat dissipating element to frequently start and stop, a hysteresis control mechanism is added to starting and stopping control of the heat dissipating element, that is, a third heat dissipating efficiency threshold Dₛₜₒₚ is preset. The third heat dissipating efficiency threshold is less than the second heat dissipating efficiency threshold. When D_{ref} output by the target adjustment function is greater than Dₛₜₐᵣₜ, the heat dissipating element starts to run. However, after the heat dissipating element starts to run, when D_{ref}<Dₛₜₒₚ, the heat dissipating element stops running. Additional losses caused by frequent starting and stopping of the heat dissipating element to the heat dissipating element is effectively reduced by using the hysteresis control mechanism.

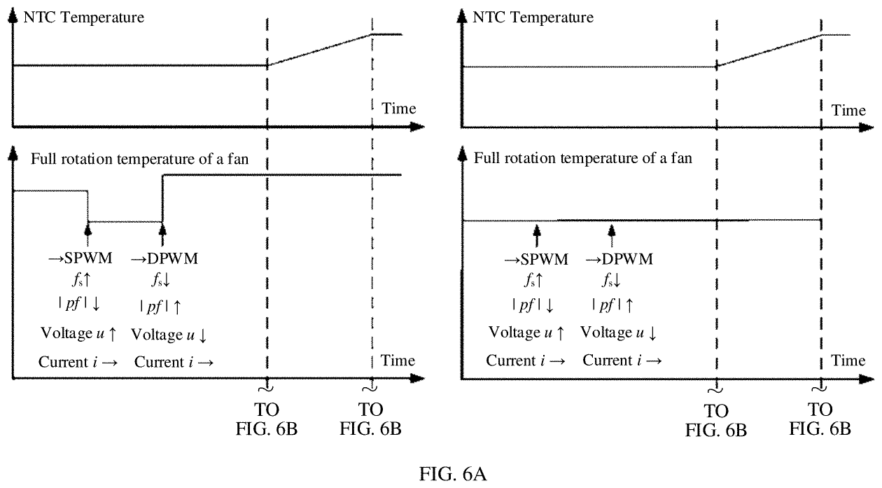

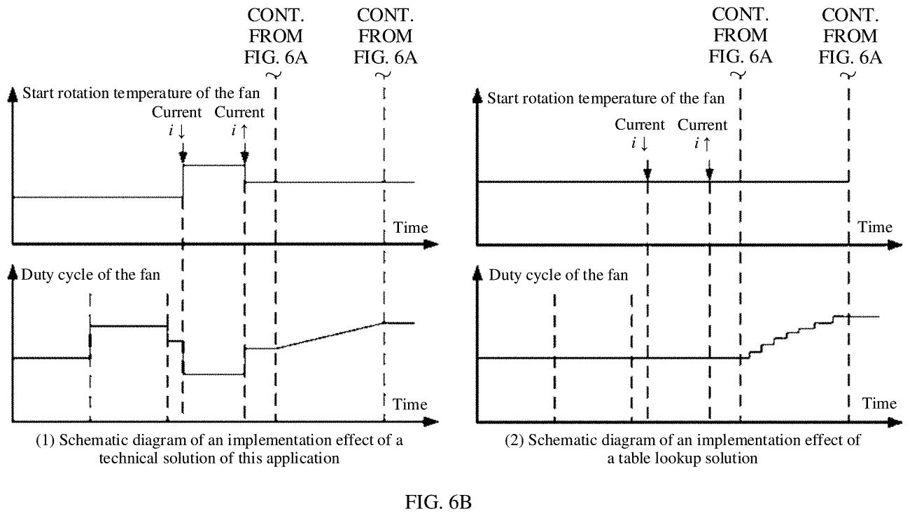

To more intuitively represent an actual effect brought by the technical solution in this embodiment, refer to FIG. 6A and FIG. 6B.

As shown in FIG. 6A and FIG. 6B, when the obtained status parameter set of the inverter changes, because an NTC resistor has hysteresis in detecting the actual temperature of the switch chip, the NTC temperature is unable to reflect an actual temperature change status of the switch chip in time. For example, the heat dissipating element is a combination of a heat dissipating fan and a heat sink. In FIG. 6A and FIG. 6B, a full rotation temperature of the fan corresponds to the first temperature parameter in the foregoing embodiment, a start rotation temperature of the fan corresponds to the second temperature parameter in the foregoing embodiment, and a duty cycle of the fan corresponds to the heat dissipating efficiency of the heat dissipating element in the foregoing embodiment.

According to the technical solution provided in this embodiment, when the obtained status parameter set (including i, u, pwm, fₛ, and |pf|) of the inverter changes, the start rotation temperature of the fan and the full rotation temperature of the fan are updated based on the change of the status parameter set, so that a duty cycle that is of the fan and that corresponds to the actual temperature of the switch chip is output when the NTC temperature does not change, thereby ensuring safe running of the switch chip and also helping increase a service life of the heat dissipating element. When the duty cycle of the fan is adjusted by using a table lookup method, even when a running status parameter of the inverter changes, the start rotation temperature of the fan and the full rotation temperature of the fan do not change. When the NTC temperature does not change, a duty cycle that is of the fan and that is found based on a preset mapping relationship table does not change, and until the NTC temperature starts to change, the duty cycle of the fan starts to change stepwise. When a quantity of points in the preset mapping relationship table is set to be excessively small, a process of switching between different duty cycles of the fan is not smooth. For the switch chip, when the running status parameter changes, the actual temperature of the switch chip has changed. However, in this method, the duty cycle of the fan is adjusted based on a change in the NTC temperature that has a hysteresis problem, and therefore safe running of the switch chip is unable to be ensured. In the technical solution of this application, an output duty cycle of the fan is adjusted in advance by adjusting values of the first temperature parameter and the second temperature parameter, to meet a heat dissipating parameter of the switch chip at the actual temperature.

The foregoing describes the heat dissipating element control method provided in the embodiments of this application, and the following describes a control apparatus provided in the embodiments of this application.

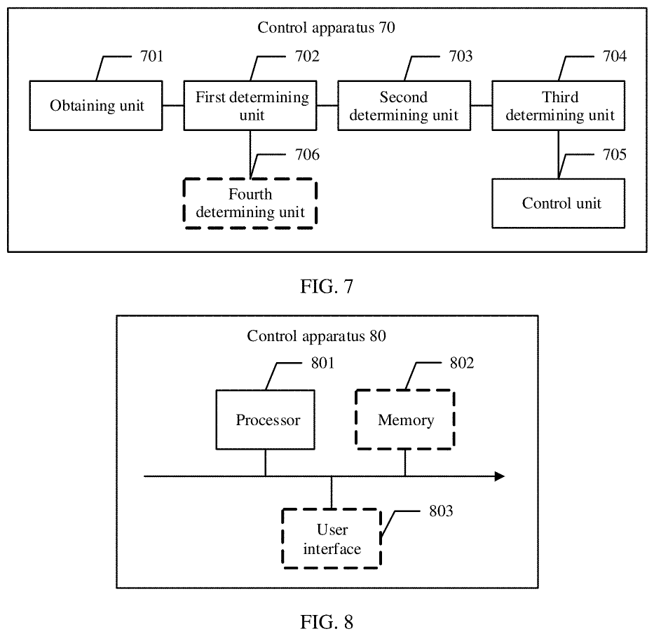

FIG. 7 is a schematic diagram of an embodiment of a control apparatus according to an embodiment of this application.

As shown in FIG. 7, a control apparatus 70 provided in this embodiment of this application includes:

an obtaining unit 701, configured to obtain a status parameter set and a detected temperature of a first device, where the status parameter set includes at least one running status parameter, and the at least one running status parameter is a parameter that affects a temperature of the first device when the first device runs;

a first determining unit 702, configured to determine a value of a first temperature parameter in a target adjustment function based on the status parameter set, where the target adjustment function is a function with the detected temperature being an independent variable and heat dissipating efficiency of a heat dissipating element being a dependent variable;

a second determining unit 703, configured to determine a value of a second temperature parameter in the target adjustment function based on the status parameter set;

a third determining unit 704, configured to determine the heat dissipating efficiency of the heat dissipating element based on the value of the first temperature parameter, the value of the second temperature parameter, and the detected temperature; and

a control unit 705, configured to control running of the heat dissipating element based on the heat dissipating efficiency of the heat dissipating element.

Optionally, as a possible design, the first determining unit 702 is configured to determine, from the status parameter set, a running status parameter associated with the first temperature parameter, to obtain a first associated parameter set; and

the first determining unit 702 is further configured to determine the value of the first temperature parameter based on a preset first mapping relationship function and the first associated parameter set, where the first mapping relationship function is used to represent a mapping relationship between the running status parameter in the first associated parameter set and the first temperature parameter.

Optionally, as a possible design, in the first mapping relationship function, the value of the first temperature parameter is a difference between a preset maximum value of the first temperature parameter and a first adjustment value, and the first adjustment value is obtained by performing weighted summation on values of running status parameters in the first associated parameter set based on weight values respectively corresponding to the running status parameters in the first associated parameter set.

Optionally, as a possible design, the control apparatus 70 further includes:

a fourth determining unit 706, configured to determine, based on a user instruction, the weight values respectively corresponding to the running status parameters in the first associated parameter set.

Optionally, as a possible design, the second determining unit 703 is configured to determine, from the status parameter set, a running status parameter associated with the second temperature parameter, to obtain a second associated parameter set; and

the second determining unit 703 is further configured to determine the value of the second temperature parameter based on a preset second mapping relationship function and the second associated parameter set, where the second mapping relationship function is used to represent a mapping relationship between the running status parameter in the second associated parameter set and the second temperature parameter.

Optionally, as a possible design, in the second mapping relationship function, the value of the second temperature parameter is a difference between a preset maximum value of the second temperature parameter and a second adjustment value, the second adjustment value is associated with a preset adjustment threshold and a ratio of a value of a target running status parameter to a rated value corresponding to the target running status parameter, and the target status parameter is a running status parameter in the second associated parameter set.

Optionally, as a possible design, when the first device is an inverter, the status parameter set includes a direct current bus voltage, an output current, a switching frequency, a modulation scheme parameter, and a power factor.

FIG. 8 is a schematic diagram of another embodiment of a control apparatus according to an embodiment of this application.

As shown in FIG. 8, a control apparatus 80 provided in this embodiment of this application includes one or more processors 801. Optionally, the control apparatus 80 further includes a memory 802. The processor 801 and the memory 802 are connected to each other by using a communications bus.

The processor 801 is a general-purpose central processing unit (CPU), a microprocessor, an ASIC, or one or more integrated circuits for controlling program execution of the solutions of this application.

The memory 802 is a read-only memory (ROM) or another type of static storage device that stores static information and an instruction, or a random access memory (RAM) or another type of dynamic storage device that stores information and an instruction; or is an electrically erasable programmable read-only memory (EEPROM), a compact disc read-only memory (CD-ROM) or another compact disc storage, an optical disc storage (including a compact disc, a laser disc, an optical disc, a digital versatile disc, and a Blu-ray disc, and the like), a magnetic disk storage medium or another magnetic storage device, or any other medium that is used to carry or store expected program code in a form of an instruction or a data structure and that is accessible by a computer. However, the memory 802 is not limited thereto. The memory 802 exists independently and is connected to the processor 801 by using the bus. Alternatively, the memory 802 is integrated with the processor 801.

The memory 802 is configured to store application program code for executing the solutions of this application, where the execution is controlled by the processor 801. The processor 801 is configured to execute the application program code stored in the memory 802.

During specific implementation, the processor 801 includes one or more CPUs, and each CPU is a single-core (single-core) processor, or is a multi-core (multi-Core) processor. The processor herein is one or more devices, circuits, and/or processing cores for processing data (such as a computer program instruction).

Optionally, the control apparatus 80 further includes a user interface 803.

The user interface 803 includes a display and a tapping device such as a keyboard, a mouse touchpad, or a touchscreen. For example, the control apparatus includes a display and a keyboard. The keyboard is configured to obtain a user instruction, to control the control apparatus to execute a user command. The display is configured to display specific values of the foregoing first temperature parameter, the second temperature parameter, and various types of preset parameter, and is further configured to display a function curve of a target adjustment function.

As another form of the embodiments, a computer-readable storage medium is provided. The computer-readable storage medium stores an instruction. When the instruction is executed, the method executed by the control apparatus in the foregoing method embodiment is executed.

As another form of the embodiments, a computer program product including instructions is provided. When the instructions are executed, the method executed by the control apparatus in the foregoing method embodiment is executed.

All or some of the foregoing embodiments are implemented by using software, hardware, firmware, or any combination thereof. When software is used to implement the embodiments, the embodiments are implemented completely or partially in a form of a computer program product.

The computer program product includes one or more computer instructions. When the computer program instructions are loaded and executed on a computer, the procedure or functions according to the embodiments of this application are all or partially generated. The computer is a general-purpose computer, a dedicated computer, a computer network, or another programmable apparatus. The computer instructions are stored in a computer-readable storage medium or is transmitted from a computer-readable storage medium to another computer-readable storage medium. For example, the computer instructions are transmitted from a website, computer, server, or data center to another website, computer, server, or data center in a wired (for example, a coaxial cable, an optical fiber, or a digital subscriber line (DSL)) or wireless (for example, infrared, radio, or microwave) manner. The computer-readable storage medium is any usable medium accessible by a computer, or a data storage device, such as a server or a data center, integrating one or more usable media. The usable medium is a magnetic medium (for example, a floppy disk, a hard disk, or a magnetic tape), an optical medium (for example, a DVD), a semiconductor medium (for example, a solid state disk (solid state disk, SSD)), or the like.

A person of ordinary skill in the art understands that all or some of the steps of the methods in the foregoing embodiments are implemented by a program by instructing related hardware. The program is stored in a computer-readable storage medium. The storage medium includes a ROM, a RAM, a magnetic disk, an optical disc, or the like.

The foregoing describes in detail the heat dissipating element control method and the control apparatus provided in the embodiments of this application. The principle and implementations of this application are described herein by applying specific examples. The foregoing description of the embodiments is merely provided to help understand the method and core ideas of this application. In addition, a person of ordinary skill in the art makes variations in terms of both the specific implementations and application scopes based on the ideas of this application. In conclusion, the content of this specification shall not be construed as a limitation to this application.

What is claimed is:

1. A heat dissipating element control method, comprising:
obtaining a status parameter set and a detected temperature of a first device, wherein the status parameter set comprises at least one running status parameter that affects a temperature of the first device when the first device runs;
determining a value of a first temperature parameter in a target adjustment function based on the status parameter set, wherein the target adjustment function being a function with the detected temperature being an independent variable and heat dissipating efficiency of a heat dissipating element being a dependent variable;
determining a value of a second temperature parameter in the target adjustment function based on the status parameter set;
determining the heat dissipating efficiency of the heat dissipating element based on the value of the first temperature parameter, the value of the second temperature parameter, and the detected temperature; and
controlling running of the heat dissipating element based on the heat dissipating efficiency of the heat dissipating element.

2. The heat dissipating element control method according to claim 1, wherein the determining the value of the first temperature parameter in the target adjustment function based on the status parameter set comprises:
determining, from the status parameter set, a running status parameter associated with the first temperature parameter, to obtain a first associated parameter set; and
determining the value of the first temperature parameter based on a preset first mapping relationship function and the first associated parameter set, wherein the preset first mapping relationship function being used to represent a mapping relationship between the running status parameter in the first associated parameter set and the first temperature parameter.

3. The heat dissipating element control method according to claim 2, wherein in the preset first mapping relationship function, the value of the first temperature parameter being a difference between a preset maximum value of the first temperature parameter and a first adjustment value, and the first adjustment value being obtained by performing weighted summation on values of running status parameters in the first associated parameter set based on weight values respectively corresponding to the running status parameters in the first associated parameter set.

4. The heat dissipating element control method according to claim 3, further comprising:
determining, based on a user instruction, the weight values respectively corresponding to the running status parameters in the first associated parameter set.

5. The heat dissipating element control method according to claim 1, wherein the determining the value of the second temperature parameter in the target adjustment function based on the status parameter set comprises:
determining, from the status parameter set, a running status parameter associated with the second temperature parameter, to obtain a second associated parameter set; and
determining the value of the second temperature parameter based on a preset second mapping relationship function and the second associated parameter set, wherein the preset second mapping relationship function being used to represent a mapping relationship between the running status parameter in the second associated parameter set and the second temperature parameter.

6. The heat dissipating element control method according to claim 5, wherein in the preset second mapping relationship function, the value of the second temperature parameter being a difference between a preset maximum value of the second temperature parameter and a second adjustment value, the second adjustment value being associated with a preset adjustment threshold and a ratio of a value of a target running status parameter to a rated value corresponding to the target running status parameter, and the target running status parameter being a running status parameter in the second associated parameter set.

7. The heat dissipating element control method according to claim 1, wherein when the first device being an inverter, the status parameter set comprises a direct current bus voltage, an output current, a switching frequency, a modulation scheme parameter, and a power factor.

8. A control apparatus, comprising:
an obtaining unit, configured to obtain a status parameter set and a detected temperature of a first device, wherein the status parameter set comprises at least one running status parameter, that affects a temperature of the first device when the first device runs;
a first determining unit, configured to determine a value of a first temperature parameter in a target adjustment function based on the status parameter set, wherein the target adjustment function being a function with the detected temperature being an independent variable and heat dissipating efficiency of a heat dissipating element being a dependent variable;
a second determining unit, configured to determine a value of a second temperature parameter in the target adjustment function based on the status parameter set;
a third determining unit, configured to determine the heat dissipating efficiency of the heat dissipating element based on the value of the first temperature parameter, the value of the second temperature parameter, and the detected temperature; and
a control unit, configured to control running of the heat dissipating element based on the heat dissipating efficiency of the heat dissipating element.

9. The control apparatus according to claim 8, wherein
the first determining unit being configured to determine, from the status parameter set, a running status parameter associated with the first temperature parameter, to obtain a first associated parameter set; and
the first determining unit being further configured to determine the value of the first temperature parameter based on a preset first mapping relationship function and the first associated parameter set, wherein the preset first mapping relationship function being used to represent a mapping relationship between the running status parameter in the first associated parameter set and the first temperature parameter.

10. The control apparatus according to claim 9, wherein in the preset first mapping relationship function, the value of the first temperature parameter being a difference between a preset maximum value of the first temperature parameter and a first adjustment value, and the first adjustment value being obtained by performing weighted summation on values of running status parameters in the first associated parameter set based on weight values respectively corresponding to the running status parameters in the first associated parameter set.

11. The control apparatus according to claim 10, wherein the control apparatus further comprises:
a fourth determining unit, configured to determine, based on a user instruction, the weight values respectively corresponding to the running status parameters in the first associated parameter set.

12. The control apparatus according to claim 8, wherein
the second determining unit being configured to determine, from the status parameter set, a running status parameter associated with the second temperature parameter, to obtain a second associated parameter set; and
the second determining unit being further configured to determine the value of the second temperature parameter based on a preset second mapping relationship function and the second associated parameter set, wherein the preset second mapping relationship function being used to represent a mapping relationship between the running status parameter in the second associated parameter set and the second temperature parameter.

13. The control apparatus according to claim 12, wherein in the preset second mapping relationship function, the value of the second temperature parameter being a difference between a preset maximum value of the second temperature parameter and a second adjustment value, the second adjustment value being associated with a preset adjustment threshold and a ratio of a value of a target running status parameter to a rated value corresponding to the target running status parameter, and the running target status parameter being a running status parameter in the second associated parameter set.

14. The control apparatus according to claim 8, wherein when the first device being an inverter, the status parameter set comprises a direct current bus voltage, an output current, a switching frequency, a modulation scheme parameter, and a power factor.

15. A control apparatus, comprising:
a processor;
a memory coupled to the processor, the memory being configured to store a computer program or instructions, and the processor being configured to execute the computer program or the instructions in the memory, to enable the control apparatus to execute a control method, wherein the method comprises:
obtaining a status parameter set and a detected temperature of a first device, wherein the status parameter set comprises at least one running status parameter that affects a temperature of the first device when the first device runs;
determining a value of a first temperature parameter in a target adjustment function based on the status parameter set, wherein the target adjustment function being a function with the detected temperature being an independent variable and heat dissipating efficiency of a heat dissipating element being a dependent variable;
determining a value of a second temperature parameter in the target adjustment function based on the status parameter set;
determining the heat dissipating efficiency of the heat dissipating element based on the value of the first temperature parameter, the value of the second temperature parameter, and the detected temperature; and
controlling running of the heat dissipating element based on the heat dissipating efficiency of the heat dissipating element.

16. A computer-readable storage medium, storing a computer program, wherein a control method being implemented when the computer program is executed, wherein the control method comprises:
obtaining a status parameter set and a detected temperature of a first device, wherein the status parameter set comprises at least one running status parameter, and the at least one running status parameter being a parameter that affects a temperature of the first device when the first device runs;
determining a value of a first temperature parameter in a target adjustment function based on the status parameter set, wherein the target adjustment function being a function with the detected temperature being an independent variable and heat dissipating efficiency of a heat dissipating element being a dependent variable;
determining a value of a second temperature parameter in the target adjustment function based on the status parameter set;
determining the heat dissipating efficiency of the heat dissipating element based on the value of the first temperature parameter, the value of the second temperature parameter, and the detected temperature; and
controlling running of the heat dissipating element based on the heat dissipating efficiency of the heat dissipating.

17. The computer-readable storage medium according to claim 1, wherein the control method further comprises:
determining, from the status parameter set, a running status parameter associated with the first temperature parameter, to obtain a first associated parameter set; and
determining the value of the first temperature parameter based on a preset first mapping relationship function and the first associated parameter set, wherein the preset first mapping relationship function being used to represent a mapping relationship between the running status parameter in the first associated parameter set and the first temperature parameter.

18. The computer-readable storage medium according to claim 17, wherein in the preset first mapping relationship function, the value of the first temperature parameter being a difference between a preset maximum value of the first temperature parameter and a first adjustment value, and the first adjustment value being obtained by performing weighted summation on values of running status parameters in the first associated parameter set based on weight values respectively corresponding to the running status parameters in the first associated parameter set.

19. The computer-readable storage medium according to claim 18, wherein the control method further comprises:
determining, based on a user instruction, the weight values respectively corresponding to the running status parameters in the first associated parameter set.

20. The computer-readable storage medium according to claim 16, wherein the control method further comprises:
determining, from the status parameter set, a running status parameter associated with the second temperature parameter, to obtain a second associated parameter set; and
determining the value of the second temperature parameter based on a preset second mapping relationship function and the second associated parameter set, wherein the preset second mapping relationship function being used to represent a mapping relationship between the running status parameter in the second associated parameter set and the second temperature parameter.
